(19) United States
(12) Patent Application Publication
(10) Pub. No.: US 2014/0328009 A1
(43) Pub. Date: Nov. 6, 2014

(54) PORTABLE POWER SUPPLY DEVICE

(71) Applicant: COOLER MASTER CO., LTD., New Taipei City (TW)

(72) Inventors: Shih-Yi Chang, New Taipei City (TW); Yi-Hsuan Huang, New Taipei City (TW)

(73) Assignee: Cooler Master Co., Ltd., New Taipei City (TW)

(21) Appl. No.: 13/887,364

(22) Filed: May 5, 2013

(51) Int. Cl. H02J 7/00; H05K 5/02

(52) U.S. Cl. CPC H02J 7/0052; H05K 5/0217
USPC 361/679.01

(57) ABSTRACT

A portable power supply device includes a power casing, a power module, a first rotating member and a first electric connector. The power module is disposed in the power casing, wherein the power module at least includes a battery unit and a charge/discharge unit. The first rotating member is pivotally connected to a first end of the power casing. The first electric connector is disposed on the first rotating member and electrically connected to the power module. The first rotating member is capable of rotating with respect to the power casing, so as to orientate the first electric connector in a first direction or a second direction.

### BACKGROUND OF THE INVENTION

1. Field of the Invention

The invention relates to a portable power supply device and, more particularly, to a portable power supply device with charging and support functions.

2. Description of the Prior Art

Various portable electronic devices, such as notebook, flat computer, mobile phone, MP3 player, and so on, are powered by a battery when they are used outdoors. Therefore, a user has to fully charge the battery of the portable electronic device before going outside and has to carry other batteries for long time use. This manner is very inconvenient. To solve the aforementioned problem, a portable power supply device has been developed. The user only has to fully charge the portable power supply device and then he/she can use the portable power supply device to charge the portable electronic device outdoors. However, since the portable power supply device only has charging function without other functions for some specific purposes, the use of the portable power supply device is limited.

### SUMMARY OF THE INVENTION

The invention provides a portable power supply device with charging and support functions, so as to solve the aforementioned problems.

According to an embodiment of the invention, a portable power supply device comprises a power casing, a power module, a first rotating member and a first electric connector. The power module is disposed in the power casing, wherein the power module at least comprises a battery unit and a charge/discharge unit. The first rotating member is pivotally connected to a first end of the power casing. The first electric connector is disposed on the first rotating member and electrically connected to the power module. The first rotating member is capable of rotating with respect to the power casing, so as to orientate the first electric connector in a first direction or a second direction. In this embodiment, when the first electric connector is orientated in the first direction, the first rotating member and the power casing are I-shaped; and when the first electric connector is orientated in the second direction, the first rotating member and the power casing are L-shaped.

According to another embodiment of the invention, the portable power supply device further comprises a second rotating member pivotally connected to a second end of the power casing, the second end is opposite to the first end, and a pivotal axis of the first rotating member is perpendicular to a pivotal axis of the second rotating member. In this embodiment, the second rotating member is capable of rotating with respect to the power casing, so as to form an I shape or L shape with the power casing.

According to another embodiment of the invention, the first rotating member further comprises a first sub-rotating member and a second sub-rotating member, the second sub-rotating member is pivotally connected to the first end of the power casing, the first sub-rotating member is pivotally connected to the second sub-rotating member, the first electric connector is disposed on the first sub-rotating member, and a pivotal axis of the first sub-rotating member is perpendicular to a pivotal axis of the second sub-rotating member. In this embodiment, the second sub-rotating member is capable of rotating with respect to the power casing, so as to form an I shape or L shape with the power casing.

As mentioned in the above, a user can connect the first electric connector of the portable power supply device to a connecting port of an electronic device, so as to charge the electronic device through the power module. Furthermore, the user can rotate the rotating member (e.g. the aforementioned first rotating member, second rotating member or second sub-rotating member) pivotally connected to the power casing, so as to change the rotating member and the power casing into an L shape. Afterward, the user can connect the first electric connector of the portable power supply device to the connecting port of the electronic device, so as to charge the electronic device through the power module and support the electronic device on a plane by the L-shaped portable power supply device. Accordingly, the portable power supply device of the invention not only has charging function but also has support function, so that the use of the portable power supply device of the invention can be increased greatly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a portable power supply device according to a first embodiment of the invention, wherein the portable power supply device is I-shaped.

FIG. 2 is a perspective view illustrating the first rotating member rotating with respect to the power casing shown in FIG. 1, wherein the portable power supply device is L-shaped.

FIG. 3 is an exploded view illustrating the portable power supply device shown in FIG. 1.

FIG. 4 is a schematic diagram illustrating the components inside the portable power supply device shown in FIG. 1.

FIG. 5 is a functional block diagram illustrating the power module shown in FIG. 4.

FIG. 6 is a schematic diagram illustrating an electronic device supported on a plane by the L-shaped portable power supply device shown in FIG. 2.

FIG. 7 is a perspective view illustrating a portable power supply device according to a second embodiment of the invention.

FIG. 8 is a perspective view illustrating a portable power supply device according to a third embodiment of the invention.

FIG. 9 is a perspective view illustrating a portable power supply device according to a fourth embodiment of the invention.

FIG. 10 is a perspective view illustrating a portable power supply device according to a fifth embodiment of the invention.

FIG. 11 is a perspective view illustrating a portable power supply device according to a sixth embodiment of the invention.

FIG. 12 is a perspective view illustrating a portable power supply device according to a seventh embodiment of the invention, wherein the portable power supply device is I-shaped.

FIG. 13 is a perspective view illustrating the first rotating member and the second rotating member rotating with respect to the power casing shown in FIG. 12, wherein the portable power supply device is L-shaped.

FIG. 14 is a schematic diagram illustrating the electronic device supported on the plane by the L-shaped portable power supply device shown in FIG. 13.

FIG. 15 is a perspective view illustrating a portable power supply device according to an eighth embodiment of the invention, wherein the portable power supply device is I-shaped.

FIG. 16 is a perspective view illustrating the second sub-rotating member rotating with respect to the power casing shown in FIG. 15, wherein the portable power supply device is L-shaped.

FIG. 17 is a perspective view illustrating the first sub-rotating member rotating with respect to the second sub-rotating member shown in FIG. 16.

FIG. 18 is a schematic diagram illustrating the electronic device supported on the plane by the L-shaped portable power supply device shown in FIG. 17.

### DETAILED DESCRIPTION

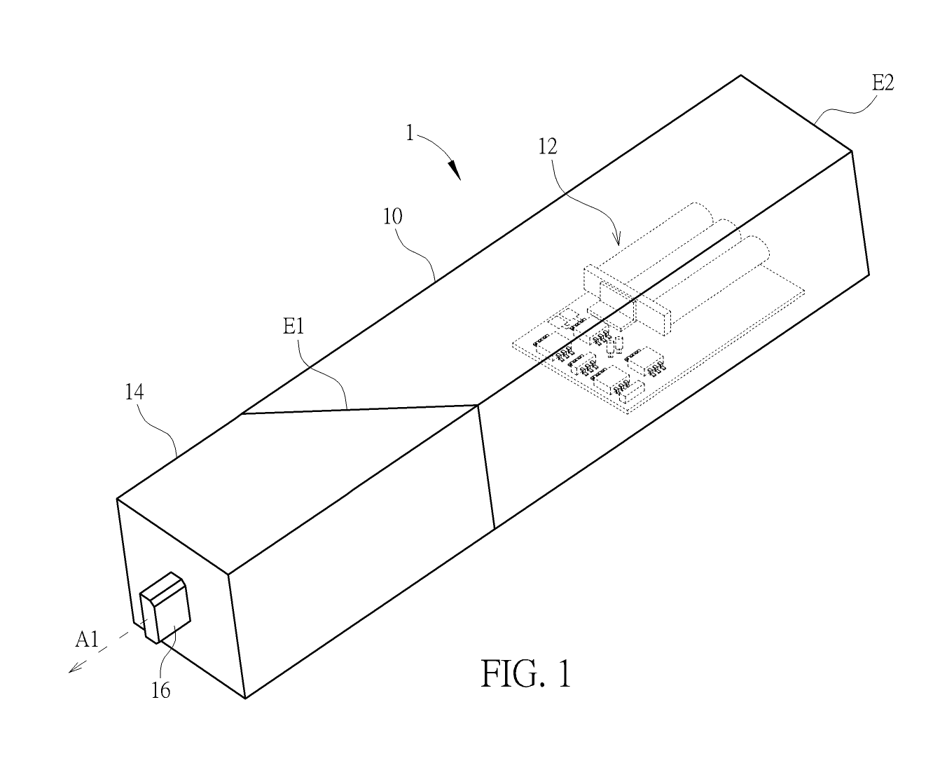

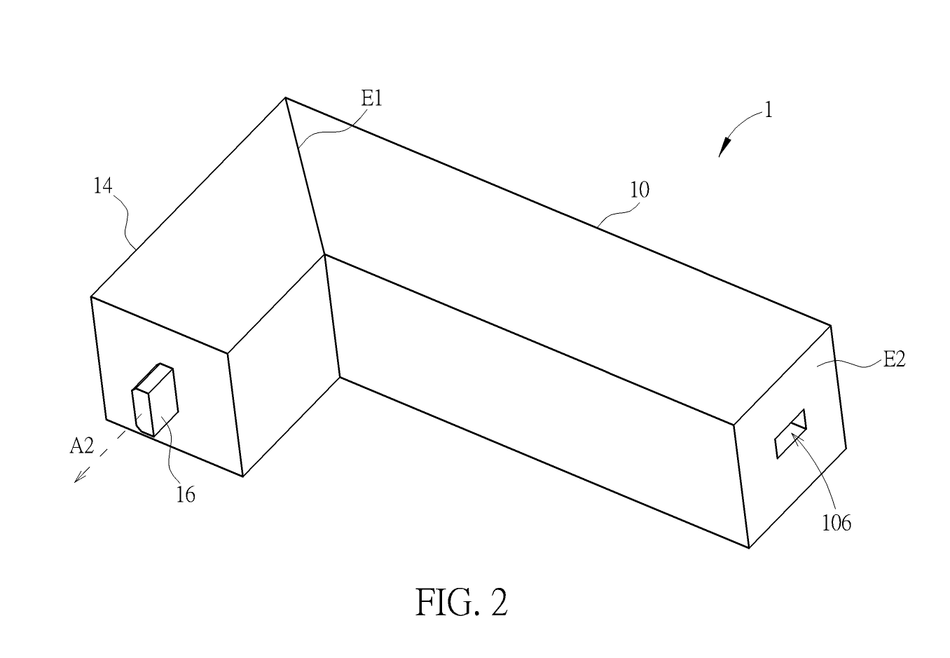

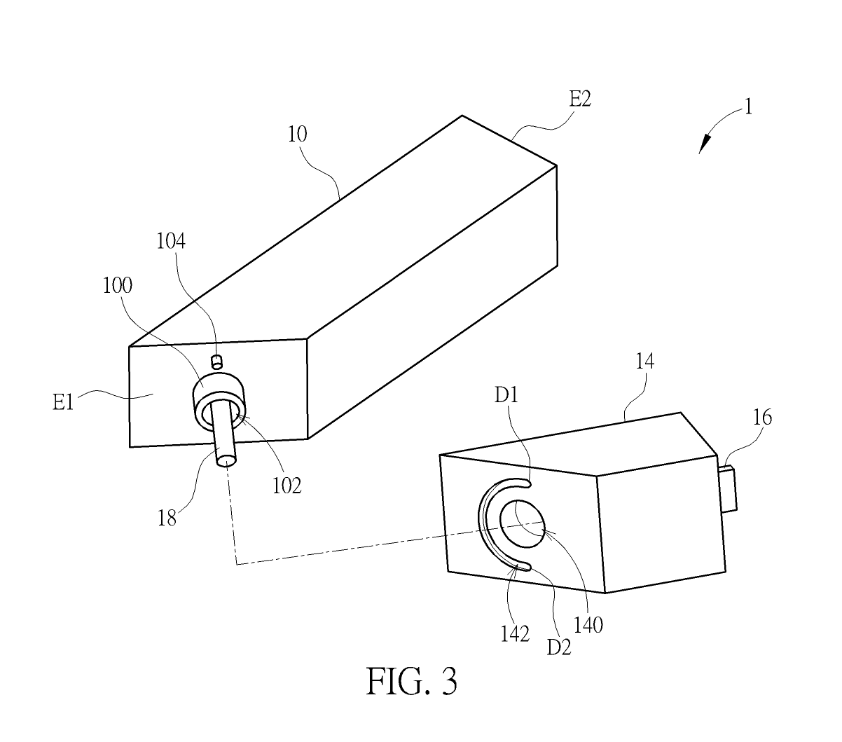

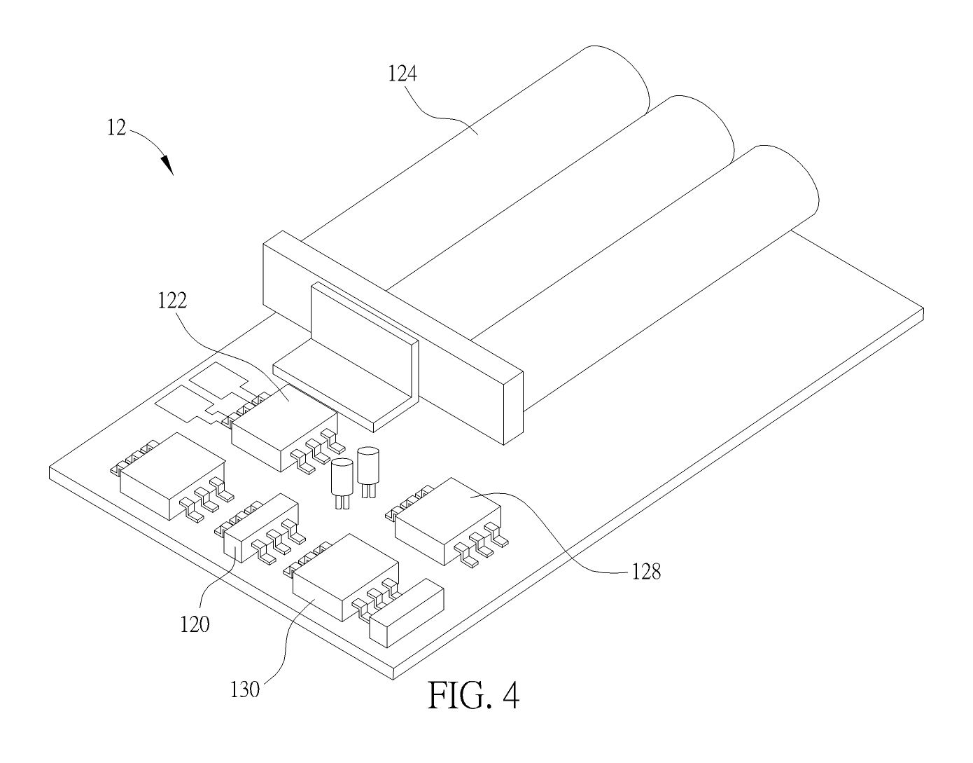

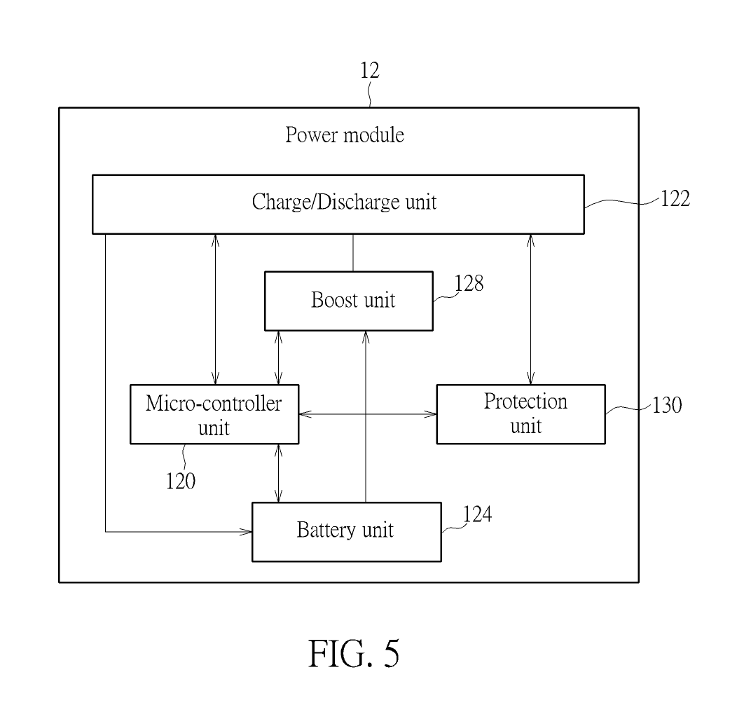

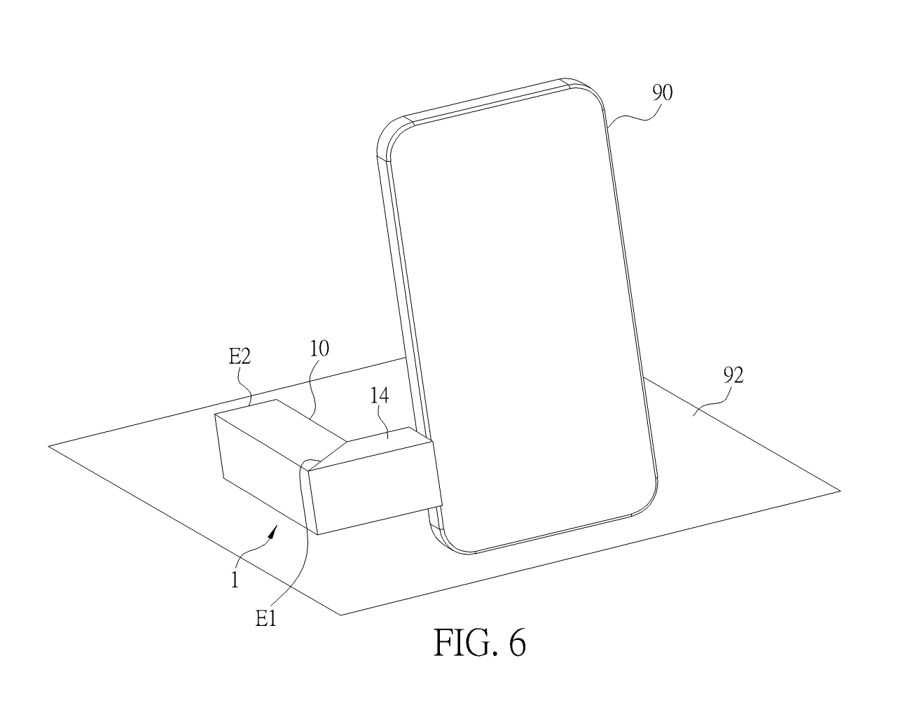

Referring to FIGS. 1 to 6, FIG. 1 is a perspective view illustrating a portable power supply device 1 according to a first embodiment of the invention, wherein the portable power supply device 1 is I-shaped; FIG. 2 is a perspective view illustrating the first rotating member 14 rotating with respect to the power casing 10 shown in FIG. 1, wherein the portable power supply device 1 is L-shaped; FIG. 3 is an exploded view illustrating the portable power supply device 1 shown in FIG. 1; FIG. 4 is a schematic diagram illustrating the components inside the portable power supply device 1 shown in FIG. 1; FIG. 5 is a functional block diagram illustrating the power module 12 shown in FIG. 4; and FIG. 6 is a schematic diagram illustrating an electronic device 90 supported on a plane 92 by the L-shaped portable power supply device 1 shown in FIG. 2.

As shown in FIGS. 1 to 5, the portable power supply device 1 comprises a power casing 10, a power module 12, a first rotating member 14, a first electric connector 16 and an electric connecting cable 18. The power module 12 is disposed in the power casing 10. The first rotating member 14 is pivotally connected to a first end E1 of the power casing 10. The first electric connector 16 is disposed on the first rotating member 14 and electrically connected to the power module 12. In this embodiment, the first electric connector 16 may be an electric connecting plug or an electric connecting port conforming to, but not limited to, Universal Serial Bus (USB) standard.

In this embodiment, the first rotating member 14 has an axial hole 140 formed thereon and the first end E1 of the power casing 10 has a pivot 100, wherein the pivot 100 is pivotally connected to the axial hole 140, so that the first rotating member 14 is capable of rotating with respect to the power casing 10, so as to orientate the first electric connector 16 in a first direction A1 (as shown in FIG. 1) or a second direction A2 (as shown in FIG. 2). In this embodiment, a length of the first rotating member 14 is shorter than a length of the power casing 10. When the first electric connector 16 is orientated in the first direction A1 shown in FIG. 1, the first rotating member 14 and the power casing 10 are I-shaped, i.e. the portable power supply device 1 is I-shaped. When the first electric connector 16 is orientated in the second direction A2 shown in FIG. 2, the first rotating member 14 and the power casing 10 are L-shaped since the length of the first rotating member 14 is shorter than the length of the power casing 10, i.e. the portable power supply device 1 is L-shaped. It should be noted that the invention may form the axial hole 140 on the first end E1 of the power casing and form the pivot 100 on the first rotating member 14 according to practical applications.

In this embodiment, the pivot 100 has a through hole 102 formed thereon. The electric connecting cable 18 passes through the through hole 102 and the axial hole 140 and is electrically connected to the power module 12 and the first electric connector 16. In this embodiment, the electric connecting cable 18 may be, but not limited to, a flexible cable. In addition, the first rotating member 14 may have a guiding groove 142 formed thereon and the first end E1 of the power casing 10 may have a pillar 104, wherein the pillar 104 is movably disposed in the guiding groove 142 when the pivot 100 is pivotally connected to the axial hole 140. When the first rotating member 14 rotates with respect to the power casing 10 and then the pillar 104 abuts against a first edge D1 of the guiding groove 142, the first electric connector 16 is orientated in the first direction A1 shown in FIG. 1. When the first rotating member 14 rotates with respect to the power casing 10 and then the pillar 104 abuts against a second edge D2 of the guiding groove 142, the first electric connector 16 is orientated in the second direction A2 shown in FIG. 2. The first edge D1 is opposite to the second edge D2, so that the first rotating member 14 is restrained from rotating between the first edge D1 and the second edge D2 of the guiding groove 142, so as to prevent the electric connecting cable 18 from being damaged or pulled apart due to over-rotation of the first rotating member 14.

As shown in FIGS. 4 and 5, the power module 12 may comprise a micro-controller unit 120, a charge/discharge unit 122, a battery unit 124, a boost unit 128 and a protection unit 130, wherein the boost unit 128 is electrically connected to the battery unit 124 and the charge/discharge unit 122, the protection unit 130 is electrically connected to the charge/discharge unit 122, and the micro-controller unit 120 is electrically connected to the battery unit 124, the charge/discharge unit 122, the boost unit 128 and the protection unit 130. In this embodiment, the charge/discharge unit 122 may be a charge/discharge circuit, the battery unit 124 may be a battery capable of being charged and discharged repeatedly, the boost unit 128 may be a boost circuit, the protection unit 130 may be a protection circuit, and the micro-controller unit 120 is used for controlling the charge/discharge unit 122, the battery unit 124, the boost unit 128 and the protection unit 130.

As shown in FIG. 2, the portable power supply device 1 further comprises a second electric connector 106 disposed on a second end E2 of the power casing 10, wherein the second end E2 is opposite to the first end E1. In this embodiment, the second electric connector 106 may be, but not limited to, an electric connecting port (e.g.

USB port). The second electric connector 106 is electrically connected to the charge/discharge unit 122 and the second electric connector 106 can be connected to an indoor socket through an electric connecting cable (not shown), so as to charge the power module 12. When the charge/discharge unit 122 receives power from the second electric connector 106, the charge/discharge unit 122 will start to charge the battery unit 124.

As mentioned in the above, a user can rotate the first rotating member 14 with respect to the power casing 10, so as to orientate the first electric connector 16 in the first direction A1 shown in FIG. 1 or the second direction A2 shown in FIG. 2. No matter which direction the first electric connector 16 is orientated in, the user can always connect the first electric connector 16 of the portable power supply device 1 to a connecting port (not shown) of an electronic device 90 shown in FIG. 6, so as to charge the electronic device 90 through the power module 12. When the power module 12 charges the electronic device 90, the battery unit 124 provides power for the boost unit 128. Then, the boost unit 128 boosts the power provided by the battery unit 124 and outputs the boosted power to the charge/discharge unit 122, so as to charge the electronic device 90. The protection unit 130 is used for monitoring an inner circuit of the power module 12, such as the work status of the charge/discharge unit 122. When the power module 12 is over-charged, over-loaded or damaged, the protection unit 130 will terminate charging of the electronic device 90.

As shown in FIGS. 2 and 6, after the user rotates the first rotating member 14 pivotally connected to the power casing 10, so as to change the first rotating member 14 and the power casing 10 into an L shape, the user can connect the first electric connector 16 of the portable power supply device 1 to a connecting port (not shown) of the electronic device 90. At this time, the power module 12 of the portable power supply device 1 will start to charge the electronic device 90 and the user can utilize the L-shaped portable power supply device 1 to support the electronic device 90 on a plane 92 for viewing or operation purpose. In other words, the portable power supply device 1 of the invention not only has charging function but also has support function, so that the use of the portable power supply device 1 of the invention can be increased greatly. It should be noted that the user can change the first rotating member 14 and the power casing 10 into an I shape for transportation or storage purpose. In this embodiment, a hinge or a stop mechanism may be disposed around the pivot 100. When the electronic device 90 is supported on the plane 92 by the L-shaped portable power supply device 1, the hinge or the stop mechanism can prevent the first rotating member 14 from rotating with respect to the power casing 10, so as to prevent the electronic device 90 from collapsing.

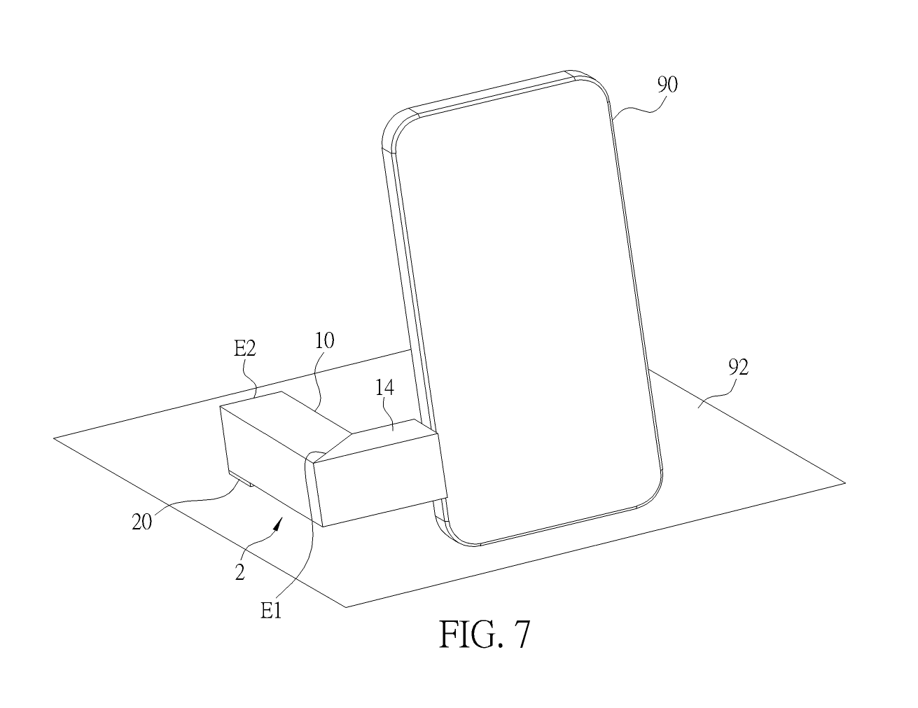

Referring to FIG. 7 along with FIG. 6, FIG. 7 is a perspective view illustrating a portable power supply device 2 according to a second embodiment of the invention. The difference between the portable power supply device 2 and the aforesaid portable power supply device 1 is that the portable power supply device 2 further comprises a skidproof pad 20 disposed on the second end E2 of the power casing 10, wherein the skidproof pad 20 may be made of rubber. Accordingly, when the user utilizes the L-shaped portable power supply device 2 to support the electronic device 90 on the plane 92 for viewing or operation purpose, the portable power supply device 2 can support the electronic device 90 on the plane 92 stably by the skidproof pad 20, so as to prevent the electronic device 90 from being damaged due to collapse. It should be noted that the same elements in FIG. 7 and FIG. 6 are represented by the same numerals, so the repeated explanation will not be depicted herein again.

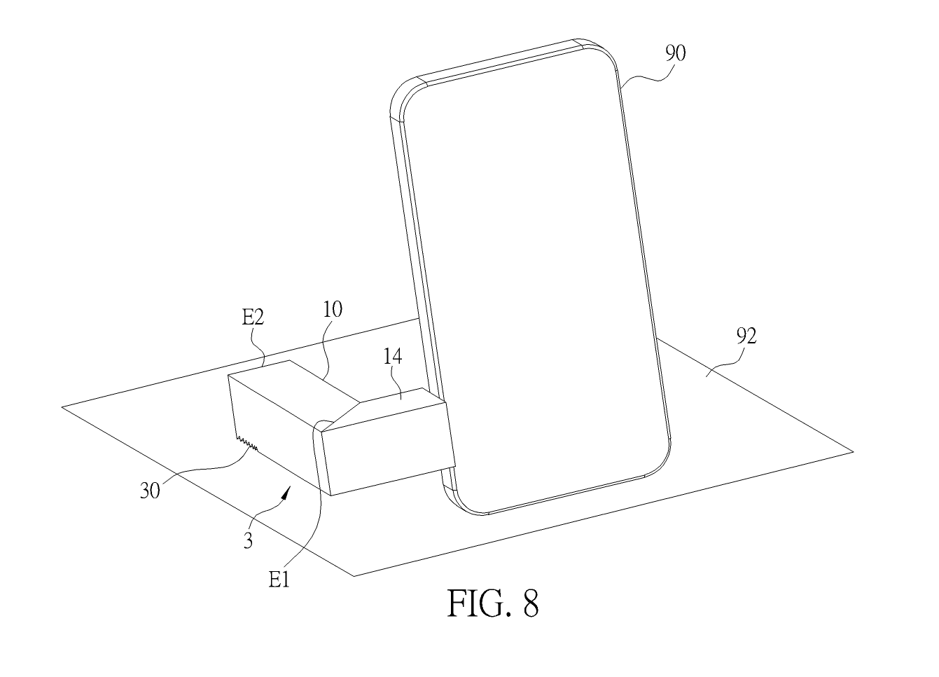

Referring to FIG. 8 along with FIG. 6, FIG. 8 is a perspective view illustrating a portable power supply device 3 according to a third embodiment of the invention. The difference between the portable power supply device 3 and the aforesaid portable power supply device 1 is that the portable power supply device 3 further comprises an uneven structure 30 (e.g. a sawtooth-shaped surface structure) formed on the second end E2 of the power casing 10. Accordingly, when the user utilizes the L-shaped portable power supply device 3 to support the electronic device 90 on the plane 92 for viewing or operation purpose, the portable power supply device 3 can support the electronic device 90 on the plane 92 stably by the uneven structure 30, so as to prevent the electronic device 90 from being damaged due to collapse. It should be noted that the same elements in FIG. 8 and FIG. 6 are represented by the same numerals, so the repeated explanation will not be depicted herein again.

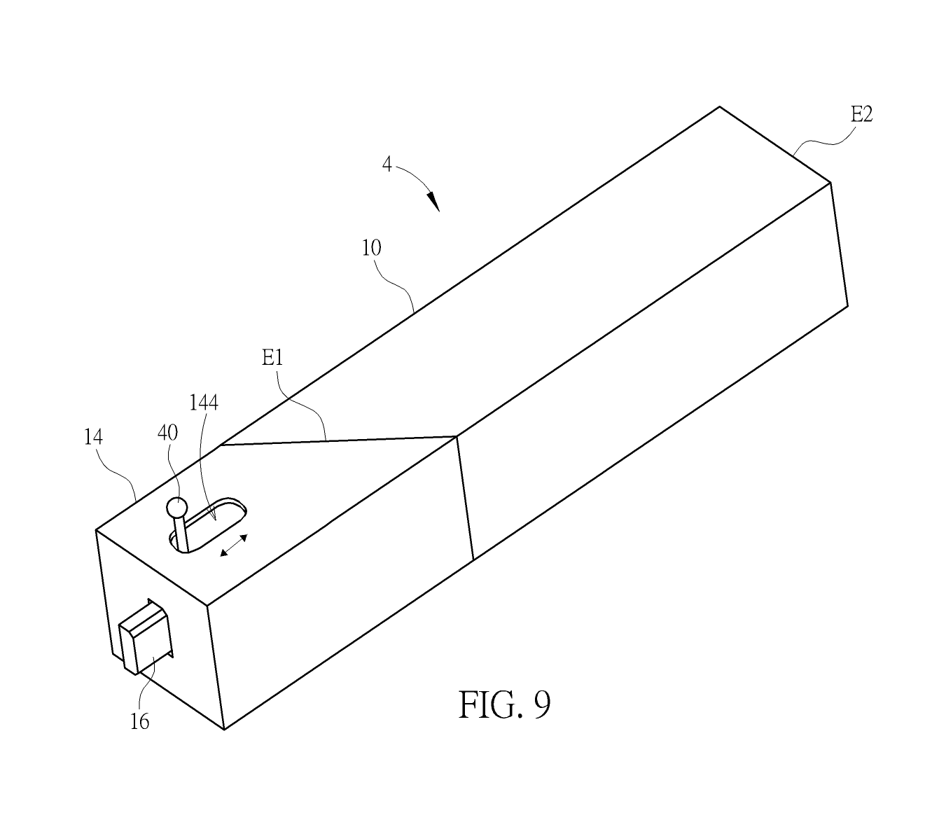

Referring to FIG. 9 along with FIG. 1, FIG. 9 is a perspective view illustrating a portable power supply device 4 according to a fourth embodiment of the invention. The difference between the portable power supply device 4 and the aforesaid portable power supply device 1 is that the portable power supply device 4 further comprises an operation member 40 and a side of the first rotating member 14 has a sliding groove 144 formed thereon, wherein the operation member 40 is movably disposed in the sliding groove 144 and connected to the first electric connector 16. In this embodiment, the operation member 40 is capable of moving with respect to the sliding groove 144 back and forth, so as to eject the first electric connector 16 out of the first rotating member 14 or retract the first electric connector 16 into the first rotating member 14. In other words, the user can push the operation member 40 to move with respect to the sliding groove 144, so as to retract the first electric connector 16 into the first rotating member 14. Accordingly, the user can carry or store the portable power supply device 4 conveniently. When the user wants to charge the electronic device with the portable power supply device 4, he/she can push the operation member 40 to move with respect to the sliding groove 144, so as to eject the first electric connector 16 out of the first rotating member 14. It should be noted that the same elements in FIG. 9 and FIG. 1 are represented by the same numerals, so the repeated explanation will not be depicted herein again.

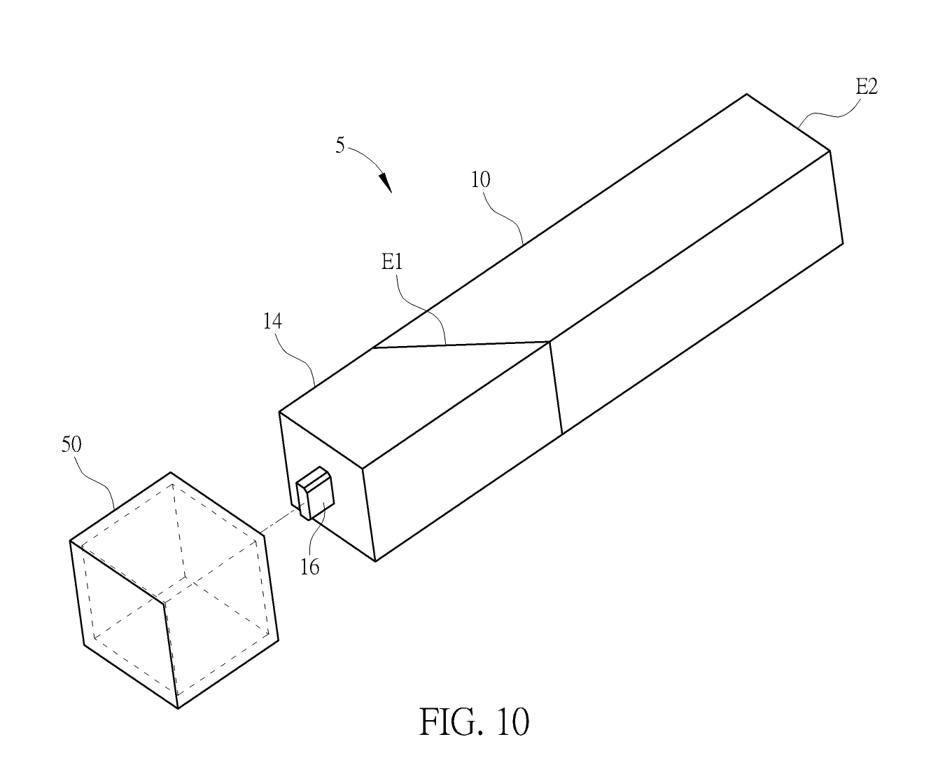

Referring to FIG. 10 along with FIG. 1, FIG. 10 is a perspective view illustrating a portable power supply device 5 according to a fifth embodiment of the invention. The difference between the portable power supply device 5 and the aforesaid portable power supply device 1 is that the portable power supply device 5 further comprises a cover 50 detachably disposed on the first rotating member 14, so as to cover the first electric connector 16. In other words, when the portable power supply device 5 is not used, the user can use the cover 50 to cover the first electric connector 16, so as to prevent the first electric connector 16 from being damaged due to dust or dirt. It should be noted that the same elements in FIG. 10 and FIG. 1 are represented by the same numerals, so the repeated explanation will not be depicted herein again.

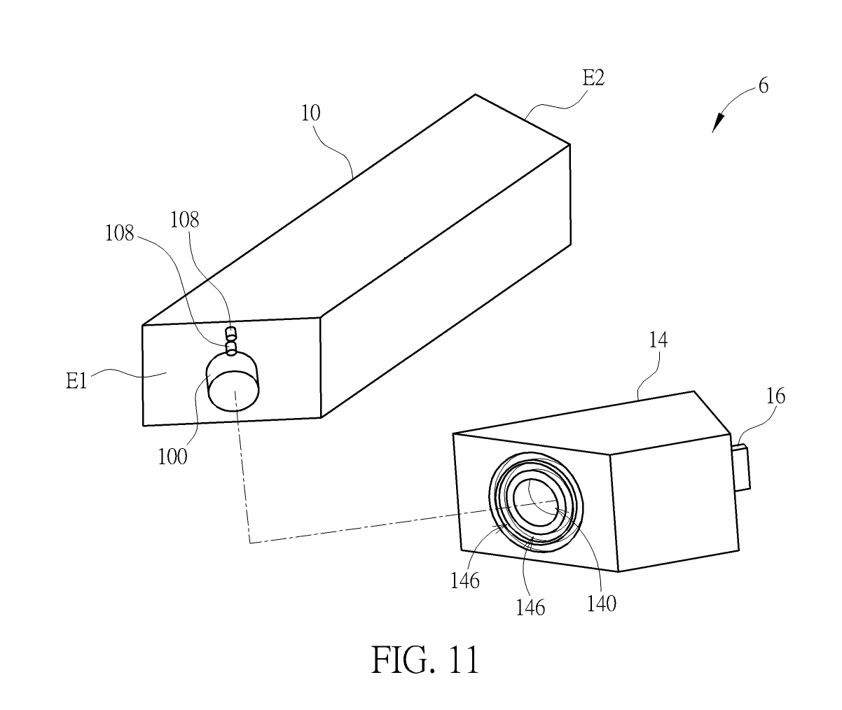

Referring to FIG. 11 along with FIG. 3, FIG. 11 is a perspective view illustrating a portable power supply device 6 according to a sixth embodiment of the invention. The difference between the portable power supply device 6 and the aforesaid portable power supply device 1 is that the first rotating member 14 of the portable power supply device 6 has two electric guiding grooves 146 formed thereon and the first end E1 of the power casing 10 of the portable power supply device 6 has two electric pillars 108 corresponding to the two electric guiding grooves 146, wherein the two electric guiding grooves 146 are electrically connected to the first electric connector 16 and the two electric pillars 108 are electrically connected to a positive power pin and a negative power pin of the power module 12, respectively. In this embodiment, when the pivot 100 is pivotally connected to the axial hole 140, the two electric pillars 108 are movably disposed in the two electric guiding grooves 146, so that the first electric connector 16 is electrically connected to the power module 12. In practical applications, the invention may form copper electrodes at the peripheries of the electric guiding grooves 146 and the electric pillars 108 to achieve the electrical connection between the first electric connector 16 and the power module 12. Therefore, the aforementioned through hole 102 formed on the pivot 100 is unnecessary in this embodiment. It should be noted that the same elements in FIG. 11 and FIG. 3 are represented by the same numerals, so the repeated explanation will not be depicted herein again.

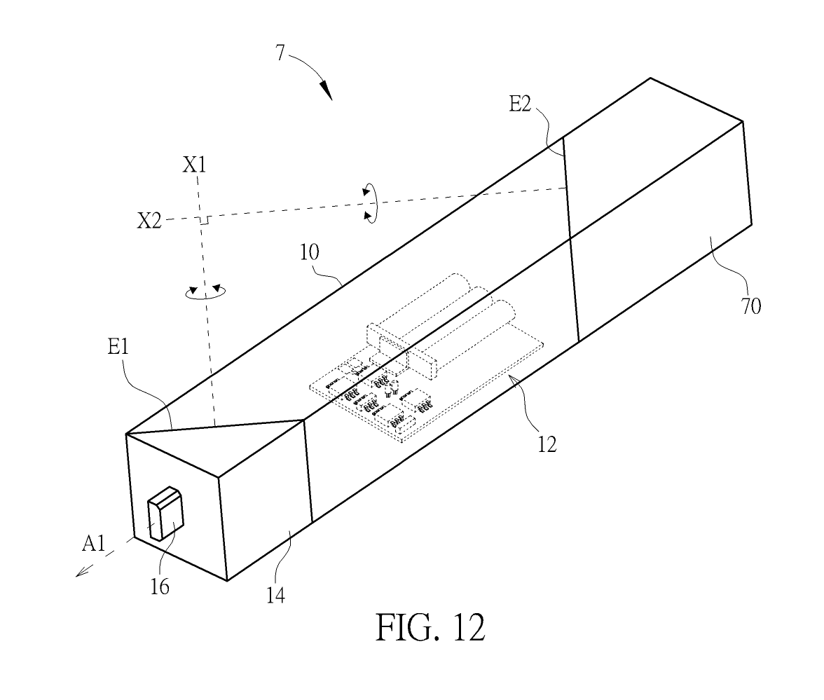

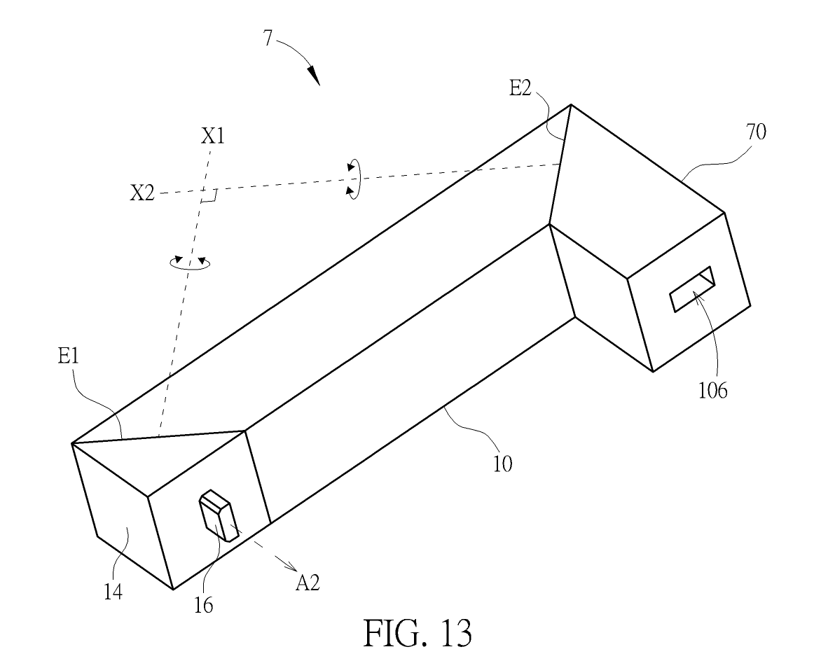

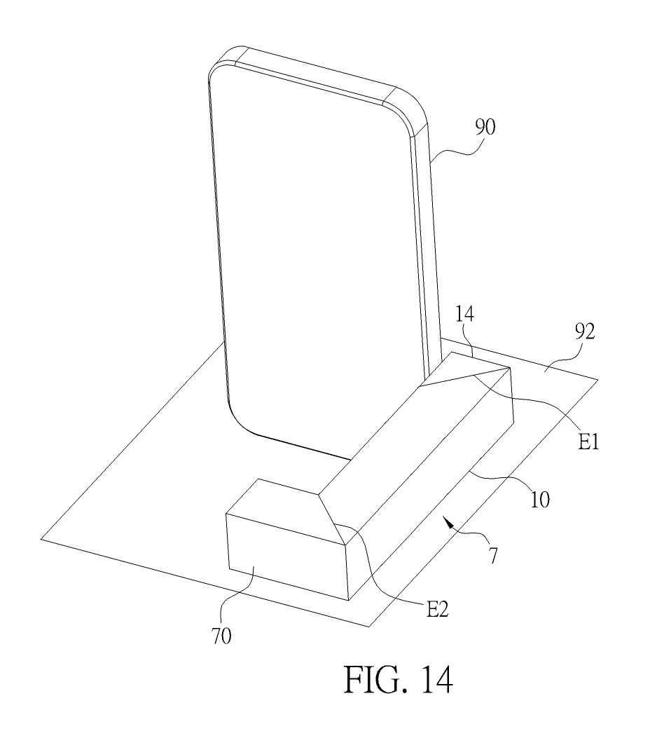

Referring to FIGS. 12 to 14 along with FIGS. 1, 2 and 6, FIG. 12 is a perspective view illustrating a portable power supply device 7 according to a seventh embodiment of the invention, wherein the portable power supply device 7 is I-shaped; FIG. 13 is a perspective view illustrating the first rotating member 14 and the second rotating member 70 rotating with respect to the power casing 10 shown in FIG. 12, wherein the portable power supply device 7 is L-shaped; and FIG. 14 is a schematic diagram illustrating the electronic device 90 supported on the plane 92 by the L-shaped portable power supply device 7 shown in FIG. 13. The difference between the portable power supply device 7 and the aforesaid portable power supply device 1 is that the portable power supply device 7 further comprises a second rotating member 70 pivotally connected to the second end E2 of the power casing and a pivotal axis X1 of the first rotating member 14 is perpendicular to a pivotal axis X2 of the second rotating member 70. In this embodiment, the first rotating member 14 is capable of rotating with respect to the power casing 10, so as to orientate the first electric connector 16 in a first direction A1 shown in FIG. 12 or a second direction A2 shown in FIG. 13. In addition, a length of the second rotating member 70 is shorter than a length of the power casing 10, and the second rotating member 70 is capable of rotating with respect to the power casing 10, so as to form an I shape shown in FIG. 12 or L shape shown in FIG. 13 with the power casing 10. It should be noted that the same elements in FIGS. 12-14 and FIGS. 1, 2 and 6 are represented by the same numerals, so the repeated explanation will not be depicted herein again.

As shown in FIGS. 13 and 14, after the user can rotate the second rotating member 70 pivotally connected to the power casing 10, so as to change the second rotating member 70 and the power casing 10 into an L shape, and rotate the first rotating member 14 pivotally connected to the power casing 10, so as to orientate the first electric connector 16 in the second direction A2, the user can connect the first electric connector 16 of the portable power supply device 7 to a connecting port (not shown) of the electronic device 90. At this time, the power module 12 of the portable power supply device 7 will start to charge the electronic device 90 and the user can utilize the L-shaped portable power supply device 7 to support the electronic device 90 on a plane 92 for viewing or operation purpose. At this time, the second rotating member 70 abuts against the plane 92, so that the portable power supply device 7 can support the electronic device 90 on the plane 92 stably, so as to prevent the electronic device 90 from being damaged due to collapse. In other words, the portable power supply device 7 of the invention not only has charging function but also has support function, so that the use of the portable power supply device 7 of the invention can be increased greatly. It should be noted that the user can change the second rotating member 70 and the power casing 10 into an I shape for transportation or storage purpose. In addition, the pivotal connecting structure between the first rotating member 14 and the power casing 10 and the pivotal connecting structure between the second rotating member 70 and the power casing 10 can be implemented by the manner shown in FIG. 3 or 11 according to practical applications.

Furthermore, as shown in FIG. 13, the portable power supply device 7 further comprises a second electric connector 106 disposed on the second rotating member 70. In this embodiment, the second electric connector 106 may be, but not limited to, an electric connecting port (e.g. USB port). The second electric connector 106 can be connected to an indoor socket through an electric connecting cable (not shown), so as to charge the power module 12.

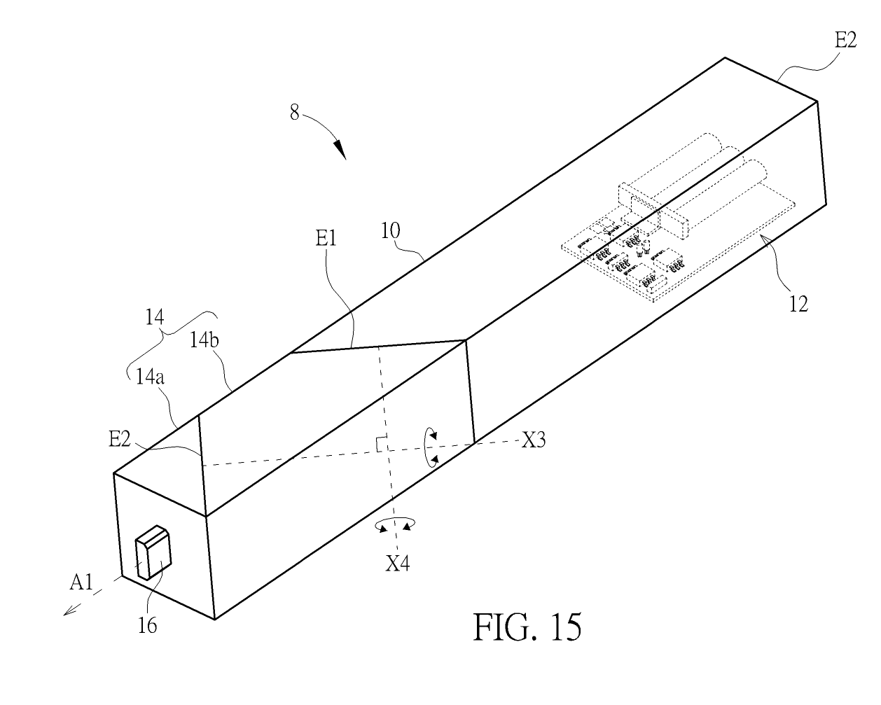

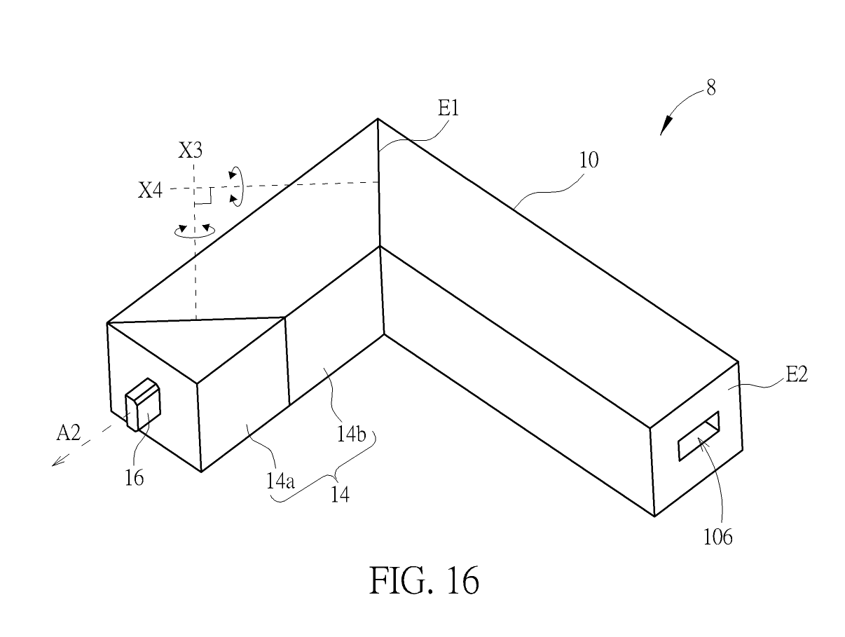

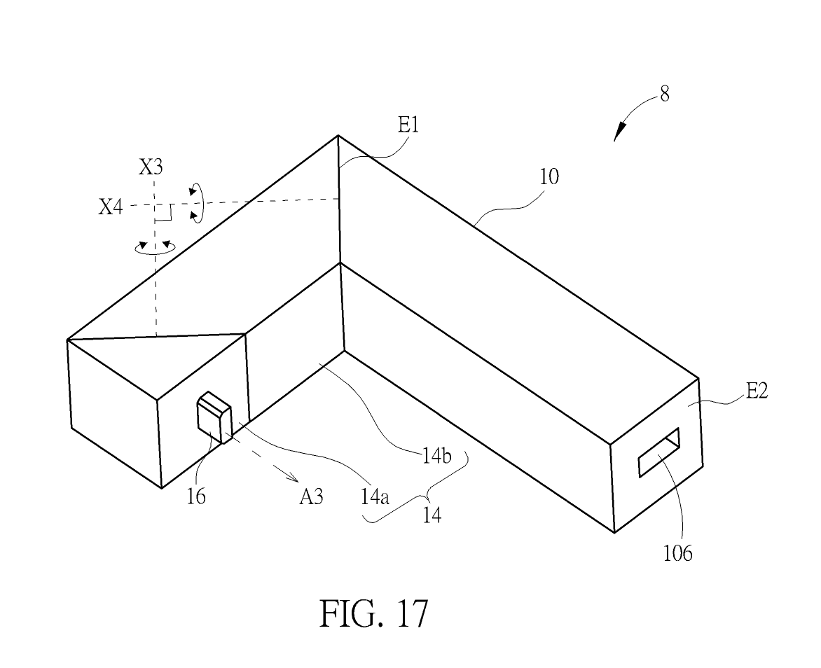

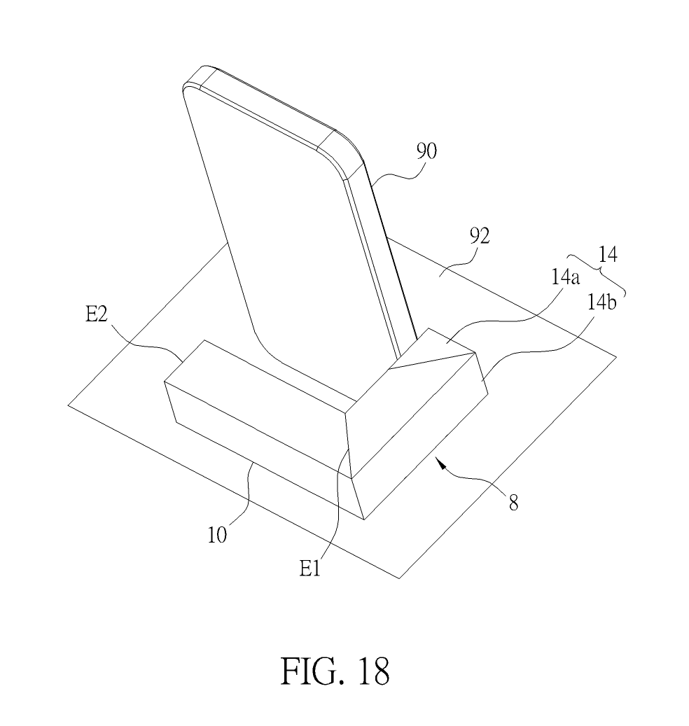

Referring to FIGS. 15 to 18 along with FIGS. 1, 2 and 6, FIG. 15 is a perspective view illustrating a portable power supply device 8 according to an eighth embodiment of the invention, wherein the portable power supply device 8 is I-shaped; FIG. 16 is a perspective view illustrating the second sub-rotating member 14b rotating with respect to the power casing 10 shown in FIG. 15, wherein the portable power supply device 8 is L-shaped; FIG. 17 is a perspective view illustrating the first sub-rotating member 14a rotating with respect to the second sub-rotating member 14b shown in FIG. 16; and FIG. 18 is a schematic diagram illustrating the electronic device 90 supported on the plane 92 by the L-shaped portable power supply device 8 shown in FIG. 17. The difference between the portable power supply device 8 and the aforesaid portable power supply device 1 is that the first rotating member 14 of the portable power supply device 8 comprises a first sub-rotating member 14a and a second sub-rotating member 14b, wherein the second sub-rotating member 14b is pivotally connected to the first end E1 of the power casing 10, the first sub-rotating member 14a is pivotally connected to the second sub-rotating member 14b, the first electric connector 16 is disposed on the first sub-rotating member 14a, and a pivotal axis X3 of the first sub-rotating member 14a is perpendicular to a pivotal axis X4 of the second sub-rotating member 14b. In this embodiment, the second sub-rotating member 14b is capable of rotating with respect to the power casing 10, so as to orientate the first electric connector 16 in a first direction A1 shown in FIG. 15 or a second direction A2 shown in FIG. 16, and the second sub-rotating member 14b and the power casing 10 can be changed into an I shape shown in FIG. 15 or L shape shown in FIGS. 16 and 17. In addition, the first sub-rotating member 14a is capable of rotating with respect to the second sub-rotating member 14b, so as to orientate the first electric connector 16 in the second direction A2 shown in FIG. 16 or a third direction A3 shown in FIG. 17. It should be noted that the same elements in FIGS. 15-18 and FIGS. 1, 2 and 6 are represented by the same numerals, so the repeated explanation will not be depicted herein again.

As shown in FIGS. 16 to 18, after the user can rotate the second sub-rotating member 14b pivotally connected to the power casing 10, so as to change the second sub-rotating member 14b and the power casing 10 into an L shape, and rotate the first sub-rotating member 14a pivotally connected to the second sub-rotating member 14b, so as to orientate the first electric connector 16 in the third direction A3, the user can connect the first electric connector 16 of the portable power supply device 8 to a connecting port (not shown) of the electronic device 90. At this time, the power module 12 of the portable power supply device 8 will start to charge the electronic device 90 and the user can utilize the L-shaped portable power supply device 8 to support the electronic device 90 on a plane 92 for viewing or operation purpose. When the user wants to take a phone call, he/she can hold the L-shaped portable power supply device 8 directly and does not need to detach the portable power supply device 8 from the electronic device 90. In other words, the portable power supply device 8 of the invention not only has charging function but also has support and holding functions, so that the use of the portable power supply device 8 of the invention can be increased greatly. It should be noted that the user can change the second sub-rotating member 14b and the power casing 10 into an I shape for transportation or storage purpose. In addition, the pivotal connecting structure between the first sub-rotating member 14a and the second sub-rotating member 14b and the pivotal connecting structure between the second sub-rotating member 14b and the power casing 10 can be implemented by the manner shown in FIG. 3 or 11 according to practical applications.

As mentioned in the above, a user can connect the first electric connector of the portable power supply device to a connecting port of an electronic device, so as to charge the electronic device through the power module. Furthermore, the user can rotate the rotating member (e.g. the aforementioned first rotating member, second rotating member or second sub-rotating member) pivotally connected to the power casing, so as to change the rotating member and the power casing into an L shape. Afterward, the user can connect the first electric connector of the portable power supply device to the connecting port of the electronic device, so as to charge the electronic device through the power module and support the electronic device on a plane by the L-shaped portable power supply device. Accordingly, the portable power supply device of the invention not only has charging function but also has support function, so that the use of the portable power supply device of the invention can be increased greatly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A portable power supply device comprising:
a power casing;
a power module disposed in the power casing, wherein the power module at least comprises a battery unit and a charge/discharge unit;
a first rotating member pivotally connected to a first end of the power casing; and
a first electric connector disposed on the first rotating member and electrically connected to the power module;
wherein the first rotating member is capable of rotating with respect to the power casing, so as to orientate the first electric connector in a first direction or a second direction.

2. The portable power supply device of claim 1, wherein a length of the first rotating member is shorter than a length of the power casing.

3. The portable power supply device of claim 2, wherein when the first electric connector is orientated in the first direction, the first rotating member and the power casing are I-shaped.

4. The portable power supply device of claim 2, wherein when the first electric connector is orientated in the second direction, the first rotating member and the power casing are L-shaped.

5. The portable power supply device of claim 1, wherein the first rotating member has an axial hole formed thereon, the first end of the power casing has a pivot, the pivot is pivotally connected to the axial hole, so that the first rotating member is capable of rotating with respect to the power casing.

6. The portable power supply device of claim 5, wherein the pivot has a through hole formed thereon, the portable power supply device further comprises an electric connecting cable, the electric connecting cable passes through the through hole and the axial hole and is electrically connected to the power module and the first electric connector.

7. The portable power supply device of claim 6, wherein the first rotating member has a guiding groove formed thereon, the first end of the power casing has a pillar, the pillar is movably disposed in the guiding groove, when the first rotating member rotates with respect to the power casing and then the pillar abuts against a first edge of the guiding groove, the first electric connector is orientated in the first direction, when the first rotating member rotates with respect to the power casing and then the pillar abuts against a second edge of the guiding groove, the first electric connector is orientated in the second direction, the first edge is opposite to the second edge.

8. The portable power supply device of claim 5, wherein the first rotating member has two electric guiding grooves formed thereon, the two electric guiding grooves are electrically connected to the first electric connector, the first end of the power casing has two electric pillars corresponding to the two electric guiding grooves, the two electric pillars are electrically connected to the power module, the two electric pillars are movably disposed in the two electric guiding grooves, so that the first electric connector is electrically connected to the power module.

9. The portable power supply device of claim 1, wherein the power module further comprises:
a boost unit electrically connected to the battery unit and the charge/discharge unit;
a protection unit electrically connected to the charge/discharge unit; and
a micro-controller unit electrically connected to the battery unit, the charge/discharge unit, the boost unit and the protection unit.

10. The portable power supply device of claim 1, further comprising an operation member, a side of the first rotating member has a sliding groove formed thereon, the operation member being movably disposed in the sliding groove and connected to the first electric connector, the operation member being capable of moving with respect to the sliding groove, so as to eject the first electric connector out of the first rotating member or retract the first electric connector into the first rotating member.

11. The portable power supply device of claim 1, further comprising a cover detachably disposed on the first rotating member, so as to cover the first electric connector.

12. The portable power supply device of claim 2, further comprising a skidproof pad disposed on a second end of the power casing, the second end being opposite to the first end.

13. The portable power supply device of claim 2, further comprising an uneven structure formed on a second end of the power casing, the second end being opposite to the first end.

14. The portable power supply device of claim 1, further comprising a second electric connector disposed on a second end of the power casing, the second end being opposite to the first end.

15. The portable power supply device of claim 1, further comprising a second rotating member pivotally connected to a second end of the power casing, the second end being opposite to the first end, a pivotal axis of the first rotating member being perpendicular to a pivotal axis of the second rotating member.

16. The portable power supply device of claim 15, wherein a length of the second rotating member is shorter than a length of the power casing.

17. The portable power supply device of claim 16, wherein the second rotating member is capable of rotating with respect to the power casing, so as to form an I shape or L shape with the power casing.

18. The portable power supply device of claim 15, further comprising a second electric connector disposed on the second rotating member.

19. The portable power supply device of claim 2, wherein the first rotating member comprises a first sub-rotating member and a second sub-rotating member, the second sub-rotating member is pivotally connected to the first end of the power casing, the first sub-rotating member is pivotally connected to the second sub-rotating member, the first electric connector is disposed on the first sub-rotating member, and a pivotal axis of the first sub-rotating member is perpendicular to a pivotal axis of the second sub-rotating member.

20. The portable power supply device of claim 19, wherein the second sub-rotating member is capable of rotating with respect to the power casing, so as to form an I shape or L shape with the power casing.

21. The portable power supply device of claim 1, wherein the first electric connector is an electric connecting plug or an electric connecting port.
